(19) United States
(12) Patent Application Publication
(10) Pub. No.: US 2026/0182223 A1
(43) Pub. Date: Jun. 25, 2026

(54) LIGHT EMITTING DISPLAY DEVICE

(71) Applicant: LG Display Co., Ltd., Seoul (KR)

(72) Inventors: HeeJung YANG, Paju-si (KR); Hoseung LEE, Paju-si (KR); MinJoo KIM, Paju-si (KR); YoungWook LEE, Paju-si (KR)

(73) Assignee: LG Display Co., Ltd., Seoul (KR)

(21) Appl. No.: 19/403,232

(22) Filed: Nov. 28, 2025

(30) Foreign Application Priority Data
Dec. 23, 2024 (KR) 10-2024-0194772

(51) Int. Cl. H10K 59/80

(52) U.S. Cl. CPC H10K 59/878; H10K 59/80515; H10K 59/80517; H10K 59/80518

(57) ABSTRACT

A light emitting display device according to an example of the present disclosure includes:
a substrate, a pixel, a driving element, a first anode electrode, an insulating layer, a second anode electrode, an emission layer and a cathode electrode. The pixel is disposed on the substrate, and includes an emission area and a non-emission area. The driving element is disposed in the non-emission area. The first anode electrode is disposed in the emission area and some of the non-emission area. The insulating layer covers the first anode electrode at the emission area, and exposes a circumferential portion of the first anode electrode. The second anode electrode is disposed on the insulating layer, and contacts the exposed circumferential portion of the first anode electrode. The emission layer is disposed on the insulating layer, the first anode electrode and the second anode electrode. The cathode electrode is disposed on the emission layer.

### CROSS-REFERENCE TO RELATED APPLICATIONS

This application claims the benefit of and priority to Korean Patent Application No. 10-2024-0194772 filed on Dec. 23, 2024, the entire contents of which are incorporated herein by reference for all purposes.

### BACKGROUND

### 1. Technical Field

The present disclosure relates to a light emitting display device. In particular, the present disclosure relates to, for example, without limitation, a bottom emission type light emitting display device having micro mirrors to enhance the light extraction efficiency.

### 2. Description of Related Art

Among the display devices, light emitting display devices may have the advantages of a wide viewing angle, excellent contrast, and fast response speed. The light emitting element used in a light emitting display device may have a light emitting layer made of organic or inorganic material between the anode electrode and the cathode electrode. Light-emitting display devices provide advantages such as high response speed, excellent brightness, and wide viewing angles. Furthermore, for instance, in OLEDs, active elements can be mounted on flexible substrates such as plastic, enabling flexible displays. However, despite these advantages, light-emitting display devices may suffer from insufficient luminous efficiency.

For instance, in the light emitting element, holes are supplied from the anode electrode and electrons are supplied from the cathode electrode, and then the electrons and holes combine at the emission layer to generate excitons. As the excitons change from the excited state to the ground state, the fluorescent molecules in the emission layer may emit light to express color.

Some of the light emitted from the emission layer of the light emitting display device may not be emitted to the outside and may be lost due to total reflection within the electrode layer having a high refractive index, or due to total reflection occurring at the interface between the emission layer and the electrodes and/or the interface between the substrate and the air. This may result in a problem of reduced light extraction efficiency.

To overcome these problems, methods are being developed to improve the light extraction efficiency of light emitting devices by forming microlenses or microcavity structures inside the devices. However, although these structures improve the luminous efficiency of light emitted in the vertical direction of the display device, they cannot extract light emitted in the horizontal direction to the vertical direction. Therefore, existing methods have limitations in improving light extraction efficiency.

The description of related art should not be considered prior art merely because it is mentioned in or associated with this section. The description of related art includes information that describes one or more aspects of the subject technology, and the description in this section does not limit the scope of the present disclosure.

### SUMMARY

One or more aspects of the present disclosure are directed to an apparatus that substantially obviates one or more problems due to limitations and disadvantages of the related art.

One or more aspects of the present disclosure provide a bottom emission type light emitting display device that maximizes light extraction efficiency by extracting light generated from the emission layer to the outside, which would otherwise be trapped inside the device and disappear due to total reflection.

Another aspect of the present disclosure provides a bottom emission type light emitting display device that improves brightness rate and light extraction efficiency by arranging a micro mirror structure on the edge of the light emitting area to maximize the area of the light emitting area.

Another aspect of the present disclosure provides a bottom emission type light emitting display device that maximize the luminous efficiency by forming a micro mirror structure in the central portion of the emission area.

Another aspect of the present disclosure provides a bottom emission type light emitting display device that maximizes light extraction efficiency by having a dual anode electrode structure to compensate for the reduction of the effective light emitting area in the emission area due to the micro mirror structure.

In order to accomplish the above-mentioned aspects and other aspects of the present disclosure, a light emitting display device according to one or more example embodiments of the present disclosure comprises: a substrate, a pixel, a driving element, a first anode electrode, an insulating layer, a second anode electrode, an emission layer and a cathode electrode. The pixel is disposed on the substrate, and includes an emission area and a non-emission area. The driving element is disposed in the non-emission area. The first anode electrode is disposed in the emission area and some of the non-emission area. The insulating layer covers the first anode electrode at the emission area, and exposes a circumferential portion of the first anode electrode. The second anode electrode is disposed on the insulating layer, and contacts the exposed circumferential portion of the first anode electrode. The emission layer is disposed on the insulating layer, the first anode electrode and the second anode electrode. The cathode electrode is disposed on the emission layer.

In an example embodiment, the insulating layer includes: an aperture exposing some middle portions of the first anode electrode.

In an example embodiment, the second anode electrode is disposed on an upper surface of the insulating layer.

In an example embodiment, the insulating layer has an island shape on the first anode electrode. The aperture has a polygonal slit shape disposed within the insulating layer.

In an example embodiment, the aperture has the polygonal slit shape having at least one of a horizontally elongated rectangle and a vertically elongated rectangle.

In an example embodiment, the aperture has the polygonal slit shape having at least one of a ‘+’ shape and a ‘X’ shape in the middle of the insulating layer.

In an example embodiment, the aperture has a plurality of polygonal slit shapes arranging at a regular interval.

In an example embodiment, an inclination angle of a sidewall of the insulating layer is in a range of 45 degree to 75 degree.

In an example embodiment, an inclined angle of a sidewall of the aperture in the insulating layer is in a range of 45 degree to 75 degree.

In an example embodiment, wherein a portion of the emission layer is disposed along the sidewall of the insulating layer, and a portion of the cathode electrode is disposed on the portion of the emission layer along the sidewall of the insulating layer so as to form a concave mirror structure.

In an example embodiment, wherein the insulating layer includes apertures, the apertures include the aperture, and a distance between the apertures is equal to or less than 20 μm.

In an example embodiment, wherein the second anode electrode is not in contact with the first anode electrode at a position where the aperture is formed.

In an example embodiment, the first anode electrode and the second anode electrode include a transparent conductive material. The insulating layer includes a transparent insulating material. The cathode electrode includes a metal material.

In an example embodiment, the transparent conductive material includes at least one of indium tin oxide (ITO), indium zinc oxide (IZO) and indium zinc tin oxide (IZTO). The transparent insulating material includes any one of silicon oxide and silicon nitride. The metal material includes any one of aluminum (Al), magnesium (Mg), calcium (Ca), silver (Ag) and an alloy thereof.

In an example embodiment, the light emitting display device further comprises: a passivation layer covering the driving element on the substrate; a color filter corresponding to the emission area on the passivation layer; a planarization layer covering the passivation layer and the color filter; and a pixel contact hole formed at the non-emission area, the pixel contact hole penetrating the planarization layer, the color filter and the passivation layer to expose some of the driving element. The first anode electrode contacts the some of the driving element via the pixel contact hole.

In an example embodiment, the insulating layer covers the pixel contact hole.

In an example embodiment, the insulating layer covers the non-emission area.

In an example embodiment, wherein a portion of the second anode electrode is deposited along a sidewall of the insulating layer so as to directly contact the circumferential portion of the first anode electrode.

In an example embodiment, wherein the portion of the second anode electrode completely surrounds an upper surface and a sidewall of the circumferential portion of the first anode electrode.

In addition, a light emitting display device according to one or more example embodiments of the present disclosure comprises: a substrate, a pixel, a driving element, a planarization layer, a first anode electrode, an insulating layer, and a second anode electrode. The pixel is disposed on the substrate and includes an emission area and a non-emission area. The driving element is located at the non-emission area. The planarization layer covers the driving element. The first anode electrode is disposed at the emission area and some of the non-emission area, the first anode electrode being disposed on the planarization layer. The insulating layer exposes circumferential portions of the first anode electrode, and covers an upper surface of the first anode electrode at the emission area. The second anode electrode extends to cover an upper surface and a sidewall of the insulating layer, to contact the exposed circumferential portions of the first anode electrode, and to contact an upper surface of the planarization layer.

In an example embodiment, the cathode electrode extends along the upper surface and the sidewall of the insulating layer.

In an example embodiment, some of the cathode electrode is disposed as facing to the sidewall of the insulating layer.

In an example embodiment, the light emitting display device further comprises: an emission layer on the insulating layer, the first anode electrode and the second anode electrode; and a cathode electrode on the emission layer.

In addition, a light emitting display device is provided according to another embodiment of the present disclosure, comprising: a substrate; a pixel on the substrate, the pixel including an emission area and a non-emission area; a driving element located at the non-emission area; a planarization layer covering the driving element; a first anode electrode, an insulating layer, and a second anode electrode sequentially disposed on the planarization layer; wherein the insulating layer and the second anode electrode are patterned into an upwardly convex shape on the first anode electrode; an emission layer covering the first anode electrode, the insulating layer, and the second anode electrode; a cathode electrode disposed on the emission layer along the convex shape; and the cathode electrode forms a concave mirror structure between the convex shapes.

In an example embodiment, wherein the first anode electrode and the second anode electrode are transmissive electrodes, and the cathode electrode is a reflective electrode.

In an example embodiment, wherein the patterned insulating layer has an inclined side surface, and an inclination angle formed by the inclined side surface relative to a horizontal surface of the substrate is in a range of 40 degrees to 80 degrees.

In an example embodiment, a step structure is formed between the patterned insulating layer and the second anode electrode.

In an example embodiment, wherein a portion of the concave mirror structure formed by the cathode electrode faces a sidewall of the insulating layer.

The light emitting display device according to one or more example embodiments of the present disclosure may have a structure in which almost all of the lights emitted from the emission layer may be extracted to the outside without being trapped and extinguished inside of the device, thereby providing a bottom emission type light emitting display device with maximized light extraction efficiency.

The light emitting display device according to one or more example embodiments of the present disclosure may provide a bottom emission type light emitting display device that minimizes non-emission areas and improve light extraction efficiency by arranging micro mirrors (or reflectors) without using a bank covering the circumferences of the pixel electrode.

The light emitting display device according to one or more example embodiments of the present disclosure may have a structure that maximizes light extraction efficiency by forming a plurality of apertures in the central portion of a pixel and by forming a micro mirror structure around the aperture, thereby extracting lights, that may be lost due to total reflection in the central portion of the pixel electrode, to the outside.

The light emitting display device according to one or more example embodiments of the present disclosure may have a structure in which an anode electrode includes a first anode electrode formed as one flat thin layer and a second anode electrode disposed on the insulating layer covering the central portions of the first anode electrode to form the micro mirrors. As a result, the entire area of the first anode electrode may be secured as the emission area. In addition, by arranging micro mirror structure at the circumferential (or boundary) area of the second anode electrode, the present disclosure may provide a bottom emission type light emitting display device that ensures the emission area to the maximum extent and improves the light extraction efficiency.

The effects that may be obtained from the present disclosure are not limited to the effects mentioned above, and other effects that are not mentioned may be clearly understood by those skilled in the art to which this disclosure belongs from the description above.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a diagram illustrating a schematic structure of a light emitting display device according to one or more example embodiments of the present disclosure.

FIG. 2 is a circuit diagram illustrating a structure of one pixel included in the light emitting display device according to an example of the present disclosure.

FIG. 3 is a plan view illustrating a structure of one pixel disposed in the light emitting display device according to a first embodiment of the present disclosure.

FIG. 4 is an enlarged cross-sectional view along to cutting line I-I′ in FIG. 3, for illustrating the structure of a light emitting display device according to the first embodiment of the present disclosure.

FIG. 5 is an enlarged cross-sectional view of dotted box ‘X’ in FIG. 4, for illustrating a structure of a light emitting diode according to the first embodiment of the present disclosure.

FIG. 6 is a plan view illustrating a structure of one pixel disposed in the light emitting display device according to a second embodiment of the present disclosure.

FIG. 7 is an enlarged cross-sectional view along to cutting line II-II′ in FIG. 6, for illustrating the structure of a light emitting display device according to the second embodiment of the present disclosure.

FIG. 8 is a plan view illustrating a structure of one pixel disposed in the light emitting display device according to a third embodiment of the present disclosure.

FIG. 9 is an enlarged cross-sectional view along to cutting line III-III′ in FIG. 8, for illustrating the structure of a light emitting display device according to the third embodiment of the present disclosure.

FIG. 10 is a schematic diagram showing that the light at the second anode electrode or between the light emitting layer and the insulating layer propagates in a horizontal direction inside the light emitting device and is reflected to the outside by the cathode electrode structure according to an embodiment of the present disclosure.

### DETAILED DESCRIPTION

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings in order to describe various example embodiments of the present disclosure, are merely given by way of example. Therefore, the present disclosure is not limited to the illustrated details. Like reference numerals refer to like elements throughout the specification unless otherwise specified. In the following description, where the detailed description of the relevant known function or configuration may unnecessarily obscure an important point of the present disclosure, a detailed description of such known function or configuration may be omitted.

Reference will now be made in detail to the exemplary embodiments of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

In the present specification, where the terms “comprise,” “have,” “include,” and the like are used, one or more other elements may be added unless the term, such as “only,” is used. An element described in the singular form is intended to include a plurality of elements, and vice versa, unless the context clearly indicates otherwise. In one or more examples, unless expressly stated otherwise, an element may be one or more elements; and an element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise.

In construing an element, the element is construed as including an error or tolerance range even where no explicit description of such an error or tolerance range is provided.

In the description of the various embodiments of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween. Also, if a first element is described as positioned “on” a second element, it does not necessarily mean that the first element is positioned above the second element in the figure. The upper part and the lower part of an object concerned may be changed depending on the orientation of the object. Consequently, where a first element is described as positioned “on” a second element, the first element may be positioned “below” the second element or “above” the second element in the figure or in an actual configuration, depending on the orientation of the object. Furthermore, the terms “left,” “right,” “top,” “bottom, “downward,” “upward,” “upper,” “lower,” and the like refer to an arbitrary frame of reference. The term spatially relative should be understood to include different orientations of the element in use or operation in addition to the orientations shown in the drawings. For example, an element described as “below” or “beneath” another element may be placed “above” another element if the elements shown in the drawings are reversed. Thus, the exemplary term “down” may include both down and up directions.

In describing a temporal relationship, when the temporal order is described as, for example, “after,” “subsequent,” “next,” or “before,” a case which is not continuous may be included unless a more limiting term, such as “just,” “immediate(ly),” or “direct(ly),” is used.

It is understood that, although the terms “first,” “second,” “A,” “B,” “(a),” “(b),” and the like may be used herein to describe various elements (e.g., layers, films, components, electrodes, structures, transistors, sections, members, parts, regions, areas, portions, steps, operations, and/or the like), these elements should not be limited by these terms, for example, to any particular order, precedence, or number of elements. Further, these are not used to define the essence or basis of the elements. These terms are merely used to refer to one element separately from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing various elements in the present disclosure, terms such as first, second, A, B, (a), and (b) may be used. These terms are used merely to distinguish one element from another, and not to define a particular nature, order, sequence, or number of the elements. Where an element is described as being “linked,” “coupled,” or “connected” to another element, that element may be directly or indirectly connected to that other element unless otherwise specified. It is to be understood that additional element or elements may be “interposed” between the two elements that are described as “linked,” “connected,” or “coupled” to each other.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in a co-dependent relationship.

Hereinafter, an example of a display apparatus according to one or more example embodiments of the present disclosure will be described in detail with reference to the attached drawings. Wherever possible, the same reference numbers will be used throughout the drawings to refer to the same or like parts.

Hereinafter, referring to figures, the present disclosure will be explained. FIG. 1 is a diagram illustrating a schematic structure of a light emitting display device according to one or more example embodiments of the present disclosure. In FIG. 1, X-axis refers to the direction parallel to the scan line, Y-axis refers to the direction of the data line, and Z-axis refers to the height direction of the display device.

Referring to FIG. 1, the light emitting display device comprises a substrate 110, a gate (or scan) driver 200, a pad portion 300, a source driving IC (Integrated Circuit) 410, a flexible circuit film 430, a circuit board 450, and a timing controller 500.

The substrate 110 may include an electrical insulating material or a flexible material. The substrate 110 may be made of a glass, a metal or a plastic, but it is not limited thereto. When the light emitting display device is a flexible display, the substrate 110 may be made of the flexible material such as plastic. For example, the substrate 110 may include a transparent polyimide material. In other embodiments, the substrate 110 may also use one or more of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA), and polystyrene (PS).

The substrate 110 may include a display area AA (or active area) and a non-display area NDA (or non-active area). The display area AA, which is an area for representing the video images, may be defined as the majority middle area of the substrate 110, but it is not limited thereto. For instance, the non-display area NDA may be an area outside of the display area AA (for example, in the vicinity of the display area AA or entirely or partly surrounding the display area AA), and may also be referred to as an edge area or a bezel area. The non-display area NDA may include a plurality of adjacent or separate non-display areas. In the display area AA, a plurality of scan lines (or gate lines), a plurality of data lines and a plurality of unit pixels may be formed or disposed. The unit pixels are arrayed in a matrix manner. Each of unit pixels may include a plurality of pixels. Each of pixels includes the scan line and the data line, respectively.

The non-display area NDA, which is an area not representing the video images, may be defined at the circumference areas of the substrate 110 surrounding all or some of the display area AA. In the non-display area NDA, the gate driver 200 and the pad portion 300 may be formed or disposed.

The gate driver 200 may supply the scan (or gate) signals to the scan lines according to the gate control signal input through the pad portion 300 from the timing controller 500. The gate driver 200 may be formed at the non-display area NDA at any one outside of the display area AA on the substrate 110, as a GIP (Gate driver In Panel) type. GIP type means that the gate driver 200 is directly formed on the substrate 110. For example, the gate driver 200 may be configured as a shift resistor, and the GIP type refers to a structure in which transistors for the shift resistor of the gate driver 200 are directly formed on the substrate 110.

The pad portion 300 may supply data signals to data lines according to a data control signal input from the timing controller 500. The pad portion 300 may be formed as a driving chip and mounted on the flexible circuit film 430. The flexible circuit film 430 may be attached to the non-display area NDA of one edge of the display area AA of the substrate 110.

The source driving IC 410 may receive the digital video data and the source control signal from the timing controller 500. The source driving IC 410 may convert the digital video data into the analog data voltages according to the source control signal and then supply that to the data lines. When the source driving IC 410 is made as a chip type, it may be installed on the flexible circuit film 430 as a COF (chip on film) or COP (chip on plastic) type.

The flexible circuit film 430 may include a plurality of first link lines connecting the pad portion 300 to the source driving IC 410, and a plurality of second link lines connecting the pad portion 300 to the circuit board 450. The flexible circuit film 430 may be attached on the pad portion 300 using an anisotropic conducting film, so that the pad portion 300 may be connected to the first link lines of the flexible circuit film 430.

The circuit board 450 may be attached to the flexible circuit film 430. The circuit board 450 may include a plurality of circuits implemented as the driving chips. For example, the timing controller 500 may be mounted on the circuit board 450. The circuit board 450 may be a printed circuit board or a flexible printed circuit board. For example, the flexible circuit board may alternatively be a flexible flat cable (FFC).

The timing controller 500 may receive the digital video data and the timing signal from an external system board through the line cables of the circuit board 450. The timing controller 500 may generate a gate control signal for controlling the operation timing of the gate driver 200 and a source control signal for controlling the source driving IC 410, based on the timing signal. The timing controller 500 may supply the gate control signal to the gate driver 200 and supply the source control signal to the source driving IC 410. Depending on the product types, the timing controller 500 may be formed of the source driving IC 410 and one chip to be mounted on the substrate 110.

### FIRST EMBODIMENT

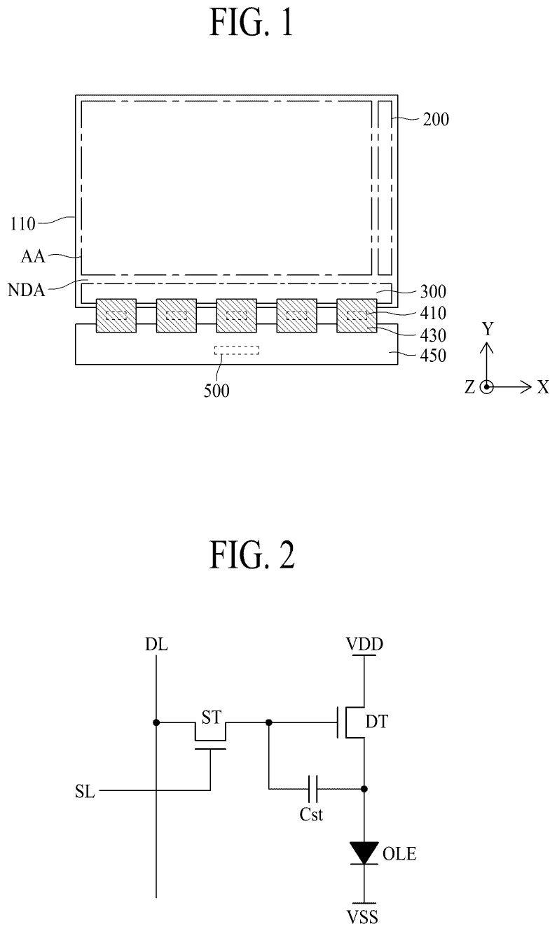

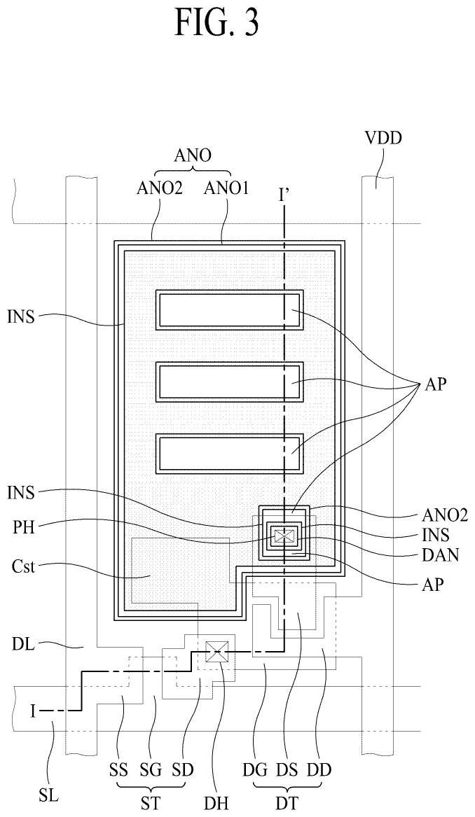

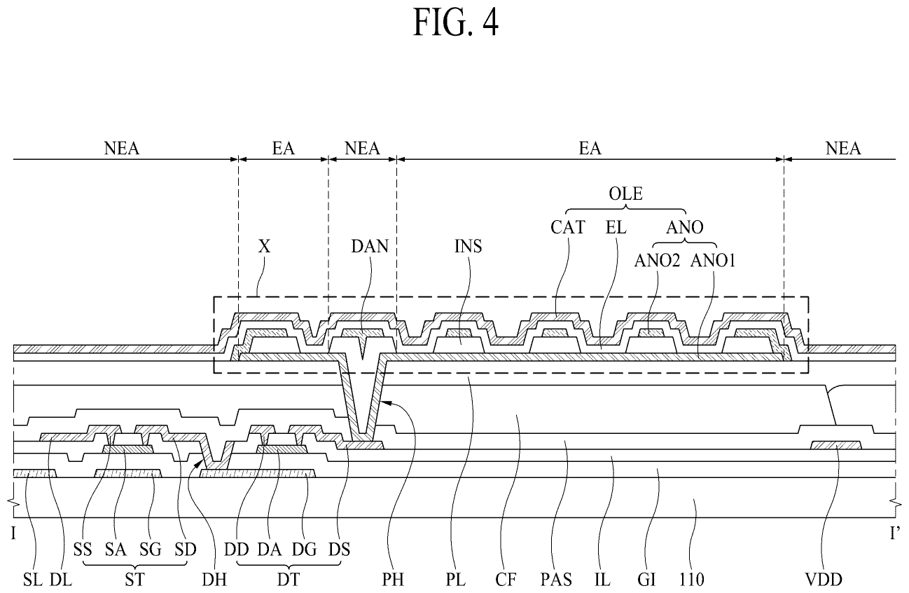

Hereinafter, referring to FIGS. 2 to 5, a preferred embodiment of the present disclosure will be explained. FIG. 2 is a circuit diagram illustrating a structure of one pixel included in the light emitting display device according to an example of the present disclosure. FIG. 3 is a plan view illustrating a structure of one pixel disposed in the light emitting display device according to a first embodiment of the present disclosure. FIG. 4 is an enlarged cross-sectional view along to cutting line I-I′ in FIG. 3, for illustrating the structure of a light emitting display device according to the first embodiment of the present disclosure.

One pixel of the light emitting display device may be defined by a scan line SL, a data line DL and a driving current line VDD. A switching thin film transistor ST, a driving thin film transistor DT, a light emitting diode OLE, and a capacitor Cst may be included in any one pixel of the light emitting display device. The driving current line VDD may be supplied with a high-level voltage for driving the light emitting diode OLE.

For example, the switching thin film transistor ST may be disposed at a location where the scan line SL and the data line DL intersect. The switching thin film transistor ST may include a gate electrode SG, a semiconductor layer SA, a source electrode SS and a drain electrode SD. The gate electrode SG may be connected to the scan line SL. The source electrode SS may be connected to the data line DL, and the drain electrode SD may be connected to the driving thin film transistor DT. The semiconductor layer SA may be disposed on a gate insulating layer GI as overlapping with the gate electrode SG. The portion of the semiconductor layer SA overlapping the gate electrode SG may be defined as a channel region.

An intermediate insulating layer IL may be deposited on the semiconductor layer SA. The source electrode SS and the drain electrode SD may be formed on the intermediate insulating layer IL. The source electrode SS may be connected to one side of the semiconductor layer SA via one contact hole formed at the intermediate insulating layer IL. The drain electrode SD may be connected to another side of the semiconductor layer SA via another contact dhole formed at the intermediate insulating layer IL. The switching thin film transistor ST may select a pixel to be driven by applying a data signal to the driving thin film transistor DT.

The driving thin film transistor DT may drive the light emitting diode OLE of the pixel selected by the switching thin film transistor ST. The driving thin film transistor DT may include a gate electrode DG, a semiconductor layer DA, a source electrode DS and a drain electrode DD. The gate electrode DG of the driving thin film transistor DT may be connected to the drain electrode SD of the switching thin film transistor ST. For example, the gate electrode DG of the driving thin film transistor DT may be connected to the drain electrode SD of the switching thin film transistor ST via a drain contact hole DH penetrating the gate insulating layer GI covering the gate electrode DG. The drain electrode DD may be connected to the driving current line VDD, and the source electrode DS may be connected to an anode electrode ANO of the light emitting diode OLE. The capacitor Cst may be disposed between the gate electrode DG of the driving thin film transistor DT and the anode electrode ANO of the light emitting diode OLE.

The intermediate insulating layer IL may be deposited on the semiconductor layer DA. The source electrode DS and the drain electrode DD may be formed on the intermediate insulating layer IL. The source electrode DS may be connected to one side of the semiconductor layer DA via one contact hole formed at the intermediate insulating layer IL. The drain electrode DD may be connected to another side of the semiconductor layer DA via another contact hole formed at the intermediate insulating layer IL.

The driving thin film transistor DT may be disposed between the driving current line VDD and the light emitting diode OLE. The driving thin film transistor DT may control the amount of current flowing from the driving current line VDD to the light emitting diode OLE according to the magnitude of the voltage of the gate electrode DG connected to the drain electrode SD of the switching thin film transistor ST.

The light emitting diode OLE may include an anode electrode ANO, an emission layer EL and a cathode electrode CAT. The light emitting diode OLE may emit lights in response to an electric current controlled by the driving thin film transistor DT. In detail, since the amount of light emitted may be adjusted according to the current controlled by the driving thin film transistor DT, the brightness of the light emitting display device may be controlled. The anode electrode ANO of the light emitting diode OLE may be connected to the source electrode DS of the driving thin film transistor DT, and the cathode electrode CAT may be connected to a low voltage line VSS to which a low potential voltage is applied. The light emitting diode OLE may be driven by the difference between a low-potential voltage and a high-potential voltage controlled by a driving thin film transistor DT.

A passivation layer PAS is deposited on the surface of the substrate 110 having the thin film transistors ST and DT. The passivation layer PAS may include an inorganic material such as silicon oxide (SiOx) or silicon nitride (SiNx). A color filter CF may be formed on the passivation layer PAS. The color filter CF may be disposed on each pixel. For example, the color filter CF may include any one of red color, blue color and green color at each pixel. For another example, the color filter CF may include any one of red color, blue color, green color and white color at each pixel.

A planarization layer PL may be deposited on the color filter CF. The planarization layer PL may be a thin film for making the surface of the substrate 110 on which thin film transistors ST and DT are formed flat. To make even the height difference, the planarization layer PL may be formed of an organic material.

A pixel contact hole PH for exposing a portion of the source electrode DS of the driving thin film transistor DT may be formed as penetrating the passivation layer PAS, the color filter CF and the planarization layer PL. An anode electrode ANO may be formed on the planarization layer PL. The anode electrode ANO may be connected to the source electrode DS of the driving thin film transistor DT via the pixel contact hole PH.

The anode electrode ANO may have different material depending on the emission type of the light emitting diode OLE. For the bottom emission type in which the light emitting diode OLE emits to the substrate 110, the anode electrode ANO may be formed of a transparent conductive material. For instance, the anode electrode ANO may be made of an oxide conductive material such as indium zinc oxide (IZO) or indium tin oxide (ITO). Further, for the top emission type in which the light emitting diode OLE emits upward opposing the substrate 110, the anode electrode ANO may be formed of a metal material having excellent light reflectance. In this case, the anode electrode ANO may have a structure in which a transparent conductive layer and a metal layer are stacked.

An emission layer EL may be deposited on the anode electrode ANO. The emission layer EL may be disposed on the entire surface of the substrate 110 as one sheet type covering continuously the upper surface of the substrate 110. A cathode electrode CAT may deposited on the emission layer EL. The cathode electrode CAT may be disposed as a thin layer shape continuously deposited on the entire surface of the substrate 110. The stacked structure of the anode electrode ANO, the emission layer EL and the cathode electrode CAT may configure the light emitting diode OLE.

The light emitting display device according to one or more example embodiments of the present disclosure may be the bottom emission type. In the case of the bottom emission type, there may be a disadvantage in that the area ratio of the aperture area to the pixel area may be relatively smaller than top emission type, due to the thin film transistor ST and DT, capacitor Cst and lines SL, DL and VDD. The light emitting display device according to one or more example embodiments of the present disclosure may provide a structure equipped with a micro mirror so that light generated from the emission layer may be provided toward the substrate 110 placed underneath without loss even though the aperture area is small.

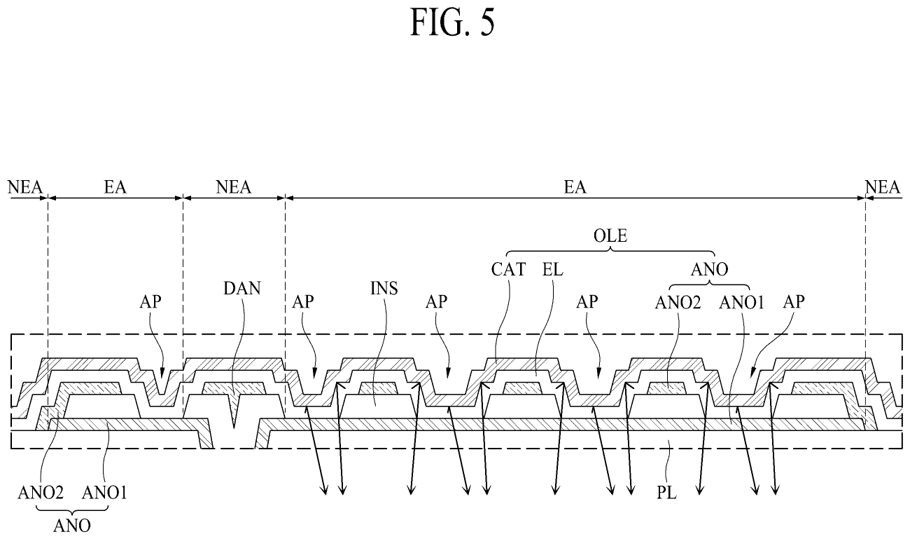

Referring to FIG. 4, the anode electrode ANO of the light emitting diode OLE may have a structure in which two electrode layers are stacked sequentially. This structure is for forming a micro-mirror structure. Hereinafter, referring to FIG. 3, FIG. 4 and FIG. 5, a structure of a light emitting diode for the bottom emission type light emitting display device having the micro-mirror will be explained. FIG. 5 is an enlarged cross-sectional view of dotted box ‘X’ in FIG. 4, for illustrating a structure of a light emitting diode according to the first embodiment of the present disclosure.

A first anode electrode ANO1 may be formed on the upper surface of the planarization layer PL. The first anode electrode ANO1 may be connected to the source electrode DS of the driving thin film transistor DT via the pixel contact hole PH.

An insulating layer INS may be deposited on the first anode electrode ANO1. The insulating layer INS may cover the middle portion of the first anode electrode ANO1, and may expose the circumferential portions of the first anode electrode ANO1. The insulating layer INS may include at least one aperture AP exposing some middle portion of the first anode electrode ANO1. Further, the insulating layer INS may include an island shape covering the pixel contact hole PH completely. FIG. 3 shows that the insulating layer INS is depicted in gray shade pattern. Referring to FIG. 4 illustrating a cross-sectional view cutting along line I-I′, the insulating layer INS may be divided into a plurality of island shapes on the first anode electrode ANO1. The portions from which the insulating layer INS is removed may be called the apertures AP. In some embodiments, the insulating layer INS may also be patterned into internal patterns inside the first anode electrode ANO1, and the inner pattern may be formed of an insulating material or other materials.

A second anode electrode ANO2 may be formed on the insulating layer INS. The circumferential portions of the first anode electrode ANO1 exposed from the insulating layer INS may be directly contacted with the second anode electrode ANO2. In detail, the second anode electrode ANO2 may be deposited along with sidewall of the insulating layer INS, and may be directly contact the circumferential portions of the first anode electrode ANO1.

Further, the second anode electrode ANO2 may be disposed as covering with the middle portion of the first anode electrode ANO1. In particular, on the insulating layer INS disposed at the middle portion of the first anode electrode ANO1, the second anode electrode ANO2 may be patterned on the middle part of the insulating layer INS, and may not be disposed at the circumferential part of the insulating layer INS.

An emission layer EL may be deposited on the upper surface of the substrate 110 having the second anode electrode ANO2. The emission layer EL may be in contact with the upper surface and the sidewall of the second anode electrode ANO2, some exposed upper surface and the sidewall of the insulating layer INS, and the first anode electrode ANO1 exposed from the apertures AP formed at the insulating layer INS.

A cathode electrode CAT may be deposited on the emission layer EL. The cathode electrode CAT may be in surface contact with the emission layer EL. With this condition, the portions of the emission layer EL disposed between the second anode electrode ANO2 and the cathode electrode CAT, and between the first anode electrode ANO1 and the cathode electrode CAT may generate lights.

The light emitting display device according to one or more example embodiments of the present disclosure may be a bottom emission type light emitting display device. Therefore, the anode electrode ANO may be made of a transparent material, and the cathode electrode CAT may be made of a metal material having excellent light reflectance.

In detail, the first anode electrode ANO1 and the second anode electrode ANO2 may include a transparent conductive material (TCO) or a semi-transmissive conductive material. For example, the first anode electrode ANO1 and the second anode electrode ANO2 may be made of a transparent conductive material such as indium-tin oxide (ITO), indium-zinc oxide (IZO) or indium-zinc-tin oxide (IZTO). For another example, the first anode electrode ANO1 and the second anode electrode ANO2 may be formed as a semi-transmissive layer of magnesium (Mg), silver (Ag) or an alloy of magnesium (Mg) and silver (Ag) with a thickness of less than 100 nm. The anode electrode ANO including the first anode electrode ANO1 and the second anode electrode ANO2 may be called as a first electrode or a transparent electrode.

It is preferable that the insulating layer INS may be made of a transparent insulating material. For example, the insulating layer INS may be made of a transparent inorganic material such as silicon oxide (SiOx) or silicon nitride (SiNx).

The cathode electrode CAT may be made of a metal material having excellent light reflectance. For example, the cathode electrode CAT may be formed of a metal material with excellent light reflectance with a thickness of at least 2,000 Å to 3,000 Å (200 nm to 300 nm). Here, the metal material having excellent light reflectance may include aluminum (Al), magnesium (Mg), calcium (Ca), silver (Ag) or alloy of them (i.e., aluminum-magnesium alloy (AlMg)) For another example, the cathode electrode CAT may include thin metal layer having high reflectance such as stack of aluminum and titanium (Ti/Al/Ti), stack of aluminum and indium tin oxide (ITO/Al/ITO), silver alloy, or stack of silver alloy and indium tin oxide (ITO/Ag alloy/ITO). Here, silver alloy may be an alloy of silver (Ag), palladium (Pd) and copper (Cu). The cathode electrode CAT may be called as a second electrode, reflection electrode, or counter electrode.

In the light emitting diode OLE of the light emitting display device according to the first embodiment, the entire area of the anode electrode ANO may be defined as the emission area EA. The area excluding the anode electrode ANO may be defined as the non-emission area NEA. The pixel contact hole PH may be included into the non-emission area NEA. On the pixel contact hole PH, the insulating layer INS may be patterned to have an island shape, and a dummy anode electrode DAN may be formed as an island shape thereon. The dummy anode electrode DAN may be disconnected from the first anode electrode ANO1 and the second anode electrode ANO2, physically and electrically. Therefore, the portion of the emission layer EL disposed between the dummy anode electrode DAN and the cathode electrode CAT may not generate light.

In FIG. 5, the second anode electrode ANO2 disposed at the left side of the dummy anode electrode DAN may be connected to the first anode electrode ANO1. Therefore, this region may be included into the emission area EA. However, the driving thin film transistor DT, a driving element such as the switching thin film transistor ST, the capacitor Cst, the scan line SL, the data line DL and/or the driving current line VDD may be disposed under the left side of the dummy anode electrode DAN. Therefore, in actual display device, even though this region is included into the emission area EA and generates light, the light may be blocked by the driving elements, so this region may not be included in the emission area.

When the light emitting diode OLE having the structure shown in FIG. 5 is operated, that is, when the pixel voltage and the common voltage are supplied to the anode electrode ANO and the cathode electrode CAT, respectively, the emission layer EL may generate lights. In FIG. 5, the light generated from the emission layer EL may be drawn arrows. Lights generated from the emission layer EL may be emitted in all 360 degree directions as a spherical wave. Here, lights radiated to the lower direction where the substrate 110 is located may pass through the color filter CF and may be emitted to the outside.

Lights radiated in upward direction where the cathode electrode CAT is disposed may be reflected by the cathode electrode CAT, pass through the color filter CF and then be emitted to the outside. Lights may be radiated from the portion of the emission layer EL disposed between the sidewall of the second anode electrode ANO2 and the cathode electrode CAT. These lights may be reflected by the cathode electrode CAT and propagate to the substrate 110, and then be emitted to the outside after passing through the color filter CF.

Among the lights generated from the emission layer EL, there may be lights reflected from the surface of the second anode electrode ANO2, the surface of the first anode electrode ANO1, or the surface of the insulating layer INS. These reflected lights may be re-reflected by the cathode electrode CAT, and then may be emitted to the outside after passing through the color filter CF.

Among the lights generated from the emission layer EL, there may be lights propagated along the horizontal direction within the second anode electrode ANO2 or within the space between the second anode electrode ANO2 and the emission layer EL (or the space between the cathode electrode CAT and the insulating layer INS) due to the total reflection (making reference to FIG. 10). In some related arts, the light propagating in the horizontal direction may not be fully extracted, thereby reducing the luminous efficiency of the display device. However, according to the combined structure of the cathode electrode, the insulating layer, and the first and second anode electrodes of the embodiments of the present disclosure to be described in the following section, the totally reflected lights within the second anode electrode ANO2 may be emitted out from the end of the second anode electrode ANO2, reflected by the cathode electrode CAT facing the end of the second anode electrode ANO2, and then emitted to the lower direction where the color filter CF is disposed.

Due to the step difference between the insulating layer INS patterned on the first anode electrode ANO1 and the second anode electrode ANO2 patterned on the insulating layer INS, the cathode electrode CAT may have a structure in which a plurality of concave mirrors having ‘∩’ shape is arrayed on the first anode electrode ANO1. Referring to FIG. 5, even though the cathode electrode CAT having the micro-mirror may have convex to upward direction, the lights generated from the emission layer EL may have an optical path reflected from the surface of the concave mirror, so the mirror is referred to as ‘concave mirror’. Most of all lights generated from the emission layer EL may be emitted to the lower direction where the substrate 110 is disposed with minimized loss of luminance.

The cathode electrode CAT may have the concave mirror having ‘∩’ shape (i.e., forming recessed portions between the protruding portions) at the sidewall of the patterned insulating layer INS, the lights may be reflected to the lower direction. Here, in order to ensure that the reflected lights propagate without being scattered downward, it is required to adjust the inclination angle of the cathode electrode CAT at the sidewall of the insulating layer INS. In order to concentrate the lights reflected in the frontal direction, it is preferable that the angle of the inclination formed by the inclined surface of the cathode electrode CAT with respect to the horizontal surface of the substrate 110 may have a degree in a range of 40 degree to 80 degree. More preferably, the inclination angle may have a degree in a range of 45 degree to 75 degree. The inclination angle of the cathode electrode CAT may be defined by the inclination angle of the etched sidewall of the insulating layer INS. Therefore, it is preferable that the inclination angle of the sidewall of the aperture AP at the insulating layer INS with respect to the horizontal plane of the substrate 110 may have a degree in a range of 45 degree to 75 degree.

Further, when forming the cathode electrode CAT to have the concave mirror shape, it is preferable that the length of the inclined surface of the cathode electrode CAT may be sufficient in order to reflect the lights generated from the emission layer EL downward effectively. The length of the inclined surface of the cathode electrode CAT may be defined by the thickness of the insulating layer INS. In order to form the micro-mirror for the cathode electrode CAT, the insulating layer INS may have a thickness of several micrometers (μm). For an example, the insulating layer INS may have a thickness in a range of 0.5 μm to 3.0 μm.

Accordingly, the present disclosure may provide a bottom emission type light emitting display device with maximized light extraction efficiency. When light extraction efficiency is maximized, luminance (or brightness) may be increased with the same power consumption, or power consumption may be reduced to provide the same luminance. Therefore, the present disclosure may provide a light emitting display device driven by low power consumption.

The cathode electrode CAT may form concave mirrors in the shape of ‘∩’ by the aperture AP formed at the insulating layer INS. The greater the number of concave mirrors, the better the light extraction efficiency due to the micro-mirror structure. When the number of apertures AP is formed too many, the area that emits lights between the first anode electrode ANO1 and the cathode electrode CAT may increase. In this case, the amount of light loss due to total reflection inside the first anode electrode ANO1 may increase. Therefore, it is preferable to set the number of apertures AP by considering the size and shape of the entire anode electrode ANO.

The second anode electrode ANO2 may be connected to the first anode electrode ANO1 physically and electrically. At the edge region of the first anode electrode ANO1, the second anode electrode ANO2 may extend along the upper surface and sidewall of the insulating layer INS, and may contact the upper edge surface of the first anode electrode ANO1 exposed from the insulating layer INS. Further, the second anode electrode ANO2 may cover the etched sidewall of the first anode electrode ANO1 and may extend to the upper surface of the planarization layer PL disposed under the first anode electrode ANO1. That is, it is preferable that the second anode electrode ANO2 may be formed so as to completely surround the upper surface of the edge and the sidewall of the first anode electrode ANO1, and to be in contact with the upper surface of the planarization layer PL. As a result, the contact resistance in electrical connection with the first anode electrode ANO1 may be reduced to a minimum value.

However, it is not limited thereto, the end of the second anode electrode ANO2 may be contact with the upper surface of the circumferences of the first anode electrode ANO1 exposed from the insulating layer INS. In this case, the area of the second anode electrode ANO2 may be ensured to the maximum extent, thereby maximizing the effective light emitting area (i.e., emission area).

Lights generated from the emission layer EL deposited on top of the second anode electrode ANO2 placed on the insulating layer INS may be incident into the second anode electrode ANO2. Among these incident lights, there may be lights that may not be emitted downward due to total reflection inside the second anode electrode ANO2, and may be guided in the horizontal direction. These guided lights may radiated from the end tip of the second anode electrode ANO2 and may be reflected by the cathode electrode CAT to be emitted to downward direction where the substrate 110 is disposed.

Here, when the optical path of the lights guided by the total reflection inside the second anode electrode ANO2 is too long, these lights may be dissipated into heat energy before reaching the end tip of the second anode electrode ANO2. Therefore, it is preferable to pattern the aperture AP of the second anode electrode ANO2 so that the length of the second anode electrode ANO2 may not be set to be too long. For example, when the optical path of the lights totally reflected inside of the second anode electrode ANO2 is longer than 20 μm, the lights may be dissipated into heat energy. Therefore, it is preferable that the length of the second anode electrode ANO2 may be equal to or less than 20 μm. In FIG. 3, the insulating layer INS is depicted in gray shade. In FIG. 3, the gray shaded area may correspond to the area where the second anode electrode ANO2 is disposed. It is preferable to adjust the size and shape of the aperture AP so that the gap in the gray shaded area in FIG. 3 may not exceed 20 μm.

In the first embodiment, the aperture AP may have a structure in which three elongated slits having an elongated shape along the horizontal direction (X-axis direction) may be arranged at a certain distance apart in the vertical direction (Y-axis direction) of the substrate 110. However, it is not limited thereto, the aperture AP may have any one of various shapes.

### SECOND EMBODIMENT

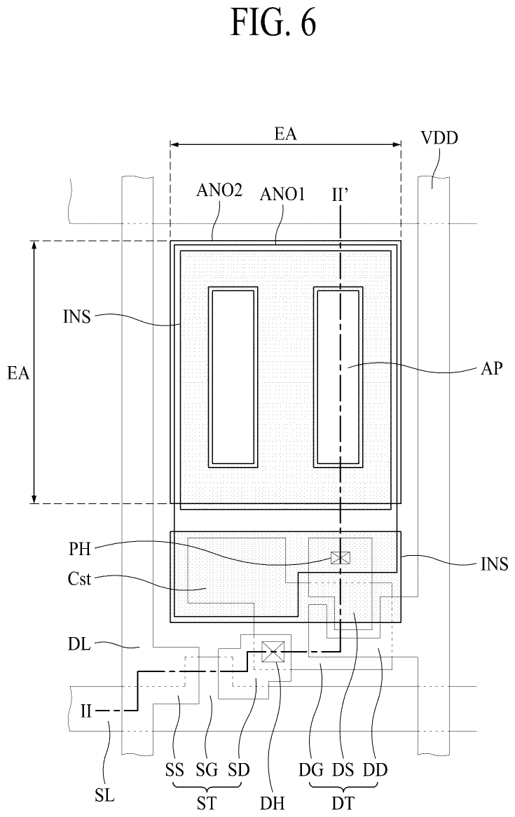

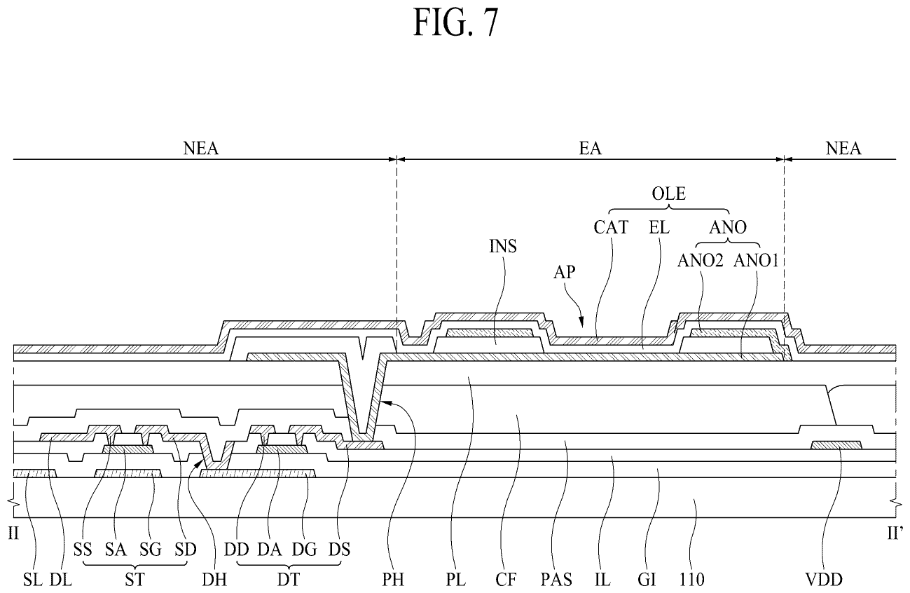

Hereinafter, referring to FIG. 6 and FIG. 7, a structure of a light emitting display device according to a second embodiment will be explained. FIG. 6 is a plan view illustrating a structure of one pixel disposed in the light emitting display device according to a second embodiment of the present disclosure. FIG. 7 is an enlarged cross-sectional view along to cutting line II-II′ in FIG. 6, for illustrating the structure of a light emitting display device according to the second embodiment of the present disclosure.

The light emitting display device according to the second embodiment may have very similar structure to that of the first embodiment. One of the different features is on the shape of the insulating layer INS and the second anode electrode ANO2 stacked on the insulating layer INS. In the following description, the structure of a light emitting diode OLE will be explained with a focus on differences from the first embodiment. Detailed descriptions for elements arranged under the first anode electrode ANO1 having the same structure as the first embodiment may not be explained, or briefly described when it is necessary.

Referring to FIG. 6 and FIG. 7, a first anode electrode ANO1 may be formed on a planarization layer PL. The first anode electrode ANO1 may have the same shape and size as that of the first embodiment. The first anode electrode ANO1 may be disposed as extending from the emission area EA to some of the driving element area included into the non-emission area NEA. The pixel contact hole PH where the first anode electrode ANO1 may contact the driving thin film transistor DT may be disposed at out of the emission area EA.

The insulating layer INS may be divided into two regions on the first anode electrode ANO1. One region may be corresponding to the emission area EA, and the other region may be corresponding to the pixel contact hole PH and overlapping with the driving element. Between the insulating layer INS placed at the emission area EA and the insulating layer INS overlapping the driving element, the insulating layer INS may be removed to expose the first anode electrode ANO1.

Further, an aperture AP may be formed by removing some of the insulating layer INS within the emission area EA. In the second embodiment, the aperture AP may have a structure in which two elongated slits along the vertical direction (Y-axis direction) of the substrate 110 may be arranged at a certain distance apart in the horizontal direction (X-axis direction). However, it is not limited thereto, various different shapes may be acceptable. It is preferable that the insulating layer INS may be formed as exposing the circumferences of the first anode electrode ANO1.

A second anode electrode ANO2 may be formed on the insulating layer INS. In particular, the second anode electrode ANO2 may have a structure covering the edge sidewall of the insulating layer INS to contact with the first anode electrode ANO1 exposed along the circumferences of the insulating layer INS. Meanwhile, where the aperture is formed, the second anode electrode ANO2 may not be contact with the first anode electrode ANO1. It is preferable that the second anode electrode ANO2 may be placed on the upper surface of the insulating layer INS as a certain distance from the edge of the aperture AP so as to completely expose the aperture AP.

FIG. 6 and FIG. 7 show that the second anode electrode ANO2 has a structure that does not cover the lower side of the insulating layer INS in the plan view, that is, the side adjacent to the pixel contact hole PH in the cross-sectional view. However, it is not limited thereto, the second anode electrode ANO2 may cover the lower side of the insulating layer INS (the etched sidewall in the cross-sectional view), and may contact the exposed portions of the first anode electrode ANO1.

In addition, at the circumferential portion of the first anode electrode ANO1, the second anode electrode ANO2 may extend along the upper surface and sidewall of the insulating layer INS, and contact to the upper surface of the circumferential portion of the first anode electrode ANO1 exposed from the insulating layer INS. The second anode electrode ANO2 may cover the etched sidewall of the first anode electrode ANO1, and may extend to the upper surface of the planarization layer PL disposed under the first anode electrode ANO1. That is, the second anode electrode ANO2 may contact to the upper surface of the planarization layer PL as completely covering the upper surface of the circumferential portion and the sidewall of the end tip of the first anode electrode ANO1. However, it is not limited thereto, the end tip of the second anode electrode ANO2 may be in contact with the upper surface of the circumferential portion of the first anode electrode ANO1 exposed from the insulating layer INS.

An emission layer EL may be deposited on the upper surface of the substrate 110 having the second anode electrode ANO2. The emission layer EL may deposited over entire of the display area AA of the substrate 110 as covering the upper surface of the insulating layer INS, the upper surface of the first anode electrode ANO1 exposed from the insulating layer INS, the upper surface and the patterned sidewall of the second anode electrode ANO2, and the patterned sidewall of the insulating layer INS.

A cathode electrode CAT may be deposited on the emission layer EL. The cathode electrode CAT may be deposited over the entire of the display area AA of the substrate 110 as being in surface contact with the emission layer EL.

Lights may be generated at the portions of the emission layer EL disposed between the anode electrode ANO and the cathode electrode CAT. That is, the portions where the first anode electrode ANO1, the emission layer EL and the cathode electrode CAT are sequentially stacked are included into the emission area EA. Further, the portions where the second anode electrode ANO2, the emission layer EL and the cathode electrode CAT are sequentially stacked may be included into the emission area EA. However, lights may not be generated at the area of the emission layer EL where the insulating layer INS, the emission layer EL and the cathode electrode CAT are sequentially stacked. That is, the portion of the emission layer EL disposed at the etched sidewall of the insulating layer INS may not generate lights.

However, lights may be reflected by the cathode electrode CAT having ‘∩’ shape on the insulating layer INS, and may be emitted to the color filter CF disposed underneath. For example, lights generated from the portion of the emission layer EL stacked on the second anode electrode ANO2 disposed on the insulating layer INS may be incident onto the second anode electrode ANO2. Among these incident lights, there may be light that is not emitted downward due to total reflection inside the second anode electrode ANO2 and is guided in the horizontal direction. These horizontally guided light may go out from the tip of the second anode electrode ANO2 and may be reflected by the cathode electrode CAT to be emitted downward.

Here, when the optical path of the light guided by total internal reflection inside the second anode electrode ANO2 may become too long, it may be dissipated into heat energy before reaching to the end tip of the second anode electrode ANO2. It is preferable to pattern the aperture AP so that the length of the second anode electrode ANO2 is not too long. For example, it is preferable that the length of the second anode electrode ANO2 may not exceed 20 μm. In FIG. 6, the insulating layer INS may be depicted in gray shading. In FIG. 6, the gray shading area may correspond to the area where the second anode electrode ANO2 is placed. Therefore, it is preferable to adjust the size and shape of the aperture AP so that the gap in the gray shading area in FIG. 6 may not exceed 20 μm.

### THIRD EMBODIMENT

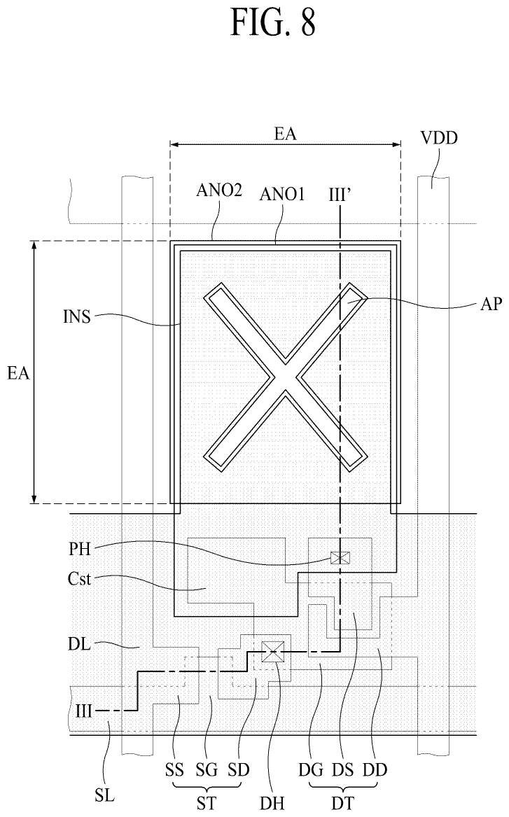

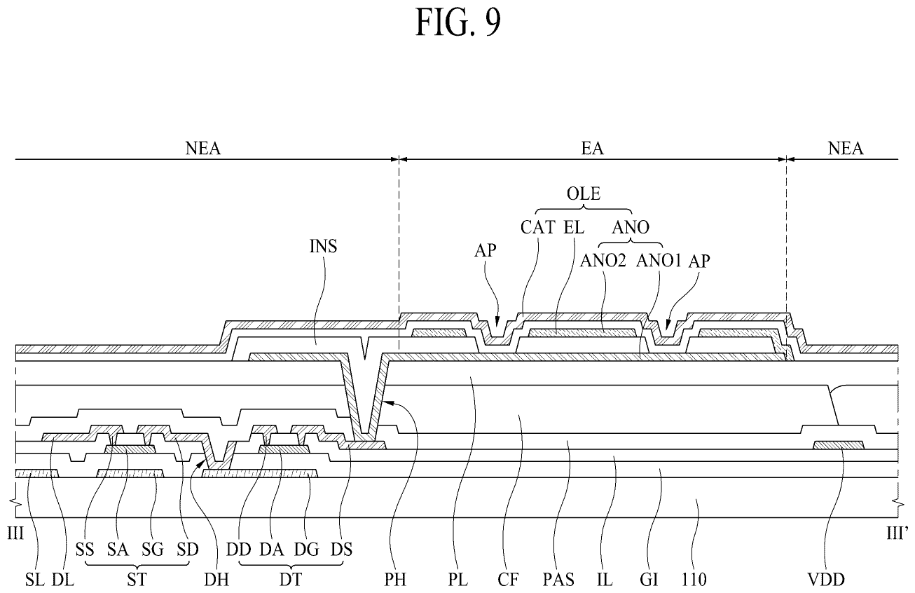

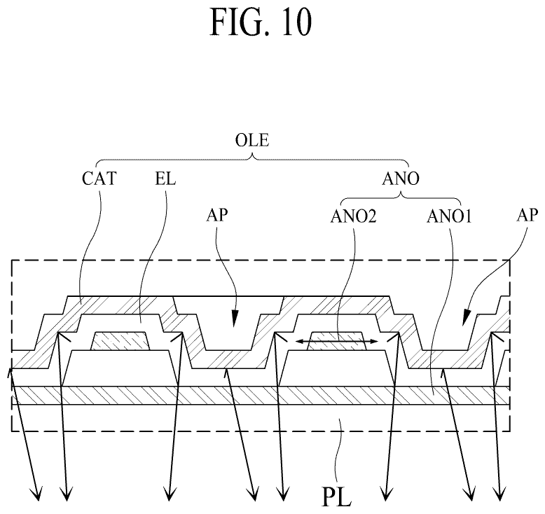

Hereinafter, referring to FIG. 8 and FIG. 9, a structure for a light emitting display device according to a third embodiment will be explained. FIG. 8 is a plan view illustrating a structure of one pixel disposed in the light emitting display device according to a third embodiment of the present disclosure. FIG. 9 is an enlarged cross-sectional view along to cutting line III-III′ in FIG. 8, for illustrating the structure of a light emitting display device according to the third embodiment of the present disclosure.

The light emitting display device according to the third embodiment may have a structure very similar to the structure of the first embodiment and/or the second embodiment. The different features may be that the shape of the insulating layer INS, the shape of the second anode electrode ANO2 stacked on the insulating layer INS, and the shape of the aperture AP. The following description may focus on the differences from the first embodiment and/or the second embodiment. The detailed description of the elements arranged under the first anode electrode ANO1 having the same structure as the first embodiment and/or the second embodiment may be omitted or briefly described when it is necessary.

Referring to FIG. 8 and FIG. 9, a first anode electrode ANO1 may be formed on a planarization layer PL. The first anode electrode ANO1 may have a same shape and size as the first anode electrode ANO1 explained in the first embodiment. The first anode electrode ANO1 may have a structure in which it may extend from the emission area EA to some area where the driving element is disposed in the non-emission area NEA. A pixel contact hole PH for connecting the first anode electrode ANO1 to the driving thin film transistor DT may be disposed out of the emission area EA.

The insulating layer INS deposited over the first anode electrode ANO1 may expose circumferential portions of the first anode electrode ANO1. Further, at least one aperture AP formed at the insulating layer INS may expose some middle portions of the first anode electrode ANO1. In addition, the insulating layer INS may have a band shape extending in the horizontal direction (X-axis direction) to cover the entire driving element area arranged along the lower edge of the emission area EA.

In FIG. 8, the insulating layer INS has a shape not covering the data line DL and the driving current line VDD. However, it is not limited thereto, the insulating layer INS may further have a band shape extending in vertical direction (Y-axis direction) to cover the data line DL and the driving current line VDD. That is, the insulating layer INS may be deposited except for the portion exposing the circumferential portions of the first anode electrode ANO1 in the emission area EA. In FIG. 8, the insulating layer INS is depicted in gray shades.

A second anode electrode ANO2 may be formed on the insulating layer INS. The second anode electrode ANO2 may be in contact with the circumferential portions of the first anode electrode ANO1 not covered by the insulating layer INS.

In addition, at the circumferential portions of the first anode electrode ANO1, the second anode electrode ANO2 may extend along the upper surface and the sidewall of the insulating layer INS, and may be in contact with the upper surface of the circumferential portions of the first anode electrode ANO1 exposed from the insulating layer INS. The second anode electrode ANO2 may extend to the upper surface of the planarization layer PL disposed under the first anode electrode ANO1, as covering the etched sidewall of the first anode electrode ANO1. That is, the second anode electrode ANO2 may be in contact with the circumferential upper surface of the first anode electrode ANO1 and the upper surface of the planarization layer PL, as fully covering the sidewall of the end tip of the first anode electrode ANO1. However, it is not limited thereto, the end tip of the second anode electrode ANO2 may be in contact with the upper surface of the circumferential portions of the first anode electrode ANO1 exposed from the insulating layer INS.

An emission layer EL may be deposited on the substrate 110 having the second anode electrode ANO2. The emission layer EL may be deposited over entire display area AA of the substrate 110, as covering the upper surface of the insulating layer INS, the upper surface of the first anode electrode ANO1 exposed from the insulating layer INS, the upper surface and the patterned sidewall of the second anode electrode ANO2, and the patterned sidewall of the insulating layer INS.

A cathode electrode CAT may be deposited on the emission layer EL. The cathode electrode CAT may be in surface contact with the emission layer EL, and deposited over entire display area AA of the substrate 110.

The portions of the emission layer EL disposed between the anode electrode ANO and the cathode electrode CAT may generate lights. That is, the region where the first anode electrode ANO1, emission layer EL and the cathode electrode CAT are sequentially stacked may be included into the emission area EA. Further, the region where the second anode electrode ANO2, the emission layer EL and the cathode electrode CAT are sequentially stacked may be included into the emission area EA. However, the region where the insulating layer INS, the emission layer EL and the cathode electrode CAT are sequentially stacked may not generate lights. That is, the portions of the emission layer EL stacked at the etched sidewall of the insulating layer INS may not generate lights.

By the cathode electrode CAT having ‘∩’ shape on the insulating layer INS, the light may be reflected to be emitted to the color filter CF disposed underneath. For example, some of lights generated from the emission layer EL stacked over the second anode electrode ANO2 disposed on the insulating layer INS may be incident onto the second anode electrode ANO2. Among these incident lights, there are lights not extracted outward due to the total reflection inside of the second anode electrode ANO2, and guided to the horizontal direction. These horizontally guided lights may go out from the tip of the second anode electrode ANO2 and may be reflected by the cathode electrode CAT to be emitted downward.

Here, when the optical path of the light guided by total internal reflection inside the second anode electrode ANO2 may become too long, it may be dissipated into heat energy before reaching to the end tip of the second anode electrode ANO2. It is preferable to pattern the aperture AP so that the length of the second anode electrode ANO2 is not too long. For example, it is preferable that the length of the second anode electrode ANO2 may not exceed 20 μm. In FIG. 8, the area depicted in gray shading may be the region where the second anode electrode ANO2 is disposed. Therefore, it is preferable to adjust the size and shape of the aperture AP so that the gap in the gray shading area in FIG. 8 may not exceed 20 μm.

In FIG. 8, the aperture AP may have a ‘X’ shape. Therefore, for the upper side, the left side, the right side and the lower side of the second anode electrode ANO2, the distance from the end tip of the second anode electrode ANO2 to the aperture AP may be longer than 20 μm. In this case, at least one auxiliary aperture having a triangular shape may be disposed between apertures AP.

The light emitting display device according to various embodiments of the present disclosure mentioned above may include a micro mirror structure that may extract lights may not be extracted from the inside of the light emitting element and may be extinguished, to the outside. Further, in order to form the micro mirror structure, a first anode electrode ANO1 may be placed at the divided portion of the second anode electrode ANO2, so as to maximize the effective light emitting area in the emission area EA. As a result, light extraction efficiency may be improved, enabling higher luminance to be provided with the same power consumption. In other words, the light emitting display device according to one or more example embodiments of the present disclosure may provide the same luminance with lower power consumption.

Some exemplary display devices of a bottom-emitting type in which the light emitting diode OLE emit light toward the substrate 110 are given above combined with the accompanying drawings. However, in some other embodiments, the display device may also be implemented as a top-emitting type in which the light emitting diode OLE emit light upward relative to the substrate 110, wherein the anode electrode ANO may be formed of a metal material having excellent light reflectivity. For instance, the anode electrode ANO may have a structure in which a transparent conductive layer and a metal layer are stacked.

In one embodiment, a light-emitting display device is provided, comprising: a substrate; a pixel on the substrate, the pixel including an emission area and a non-emission area; a driving element located at the non-emission area; a first electrode disposed in a portion of the non-emission area and the emission area; the first electrode comprises a conductive first material and an internal pattern located within the first electrode comprising a second material different from the first material, wherein all the portions of the internal pattern are below an upper surface of the first electrode and is not exposed at a lower surface of the first electrode; an emission layer disposed on the first electrode; and a second electrode disposed on the luminescent layer.

In some embodiments, wherein the emission layer and the second electrode are extended to have a shape corresponding to the first electrode to form a micro cavity or a concave mirror.

In some embodiments, wherein the first electrode is an anode, the second electrode is a cathode, and the second material includes a conductive material with lower conductivity than the first material, an insulating material, or an organic materials.

In some embodiments, wherein the internal pattern includes an aperture located in the light-emitting area, and a sidewall exposed to the aperture, the aperture exposes the first material located at the bottom of the first electrode, and a sidewall of the internal pattern extends with respect to the adjacent first material to include at least one step of a step between the lower surface and the upper surface of the internal pattern and a step from the upper surface of the internal pattern to the upper surface of the first electrode.

In some embodiments, wherein the inner pattern includes an aperture located in the emission area and exposed to the emission layer without penetrating the lower surface of the first electrode, and a sidewall of the inner pattern extending into the aperture extends with respect to the adjacent first material to include at least one of a step between the lower surface and the upper surface of the inner pattern and a step from the upper surface of the inner pattern to the upper surface of the first electrode.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet, are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A light emitting display device, comprising:
a substrate;
a pixel disposed on the substrate, the pixel including an emission area and a non-emission area;
a driving element in the non-emission area;
a first anode electrode disposed in the emission area and a portion of the non-emission area;
an insulating layer covering the first anode electrode at the emission area, and exposing a circumferential portion of the first anode electrode;
a second anode electrode on the insulating layer, the second anode electrode contacting the exposed circumferential portion of the first anode electrode;
an emission layer on the insulating layer, the first anode electrode and the second anode electrode; and
a cathode electrode on the emission layer.

2. The light emitting display device according to claim 1, wherein the insulating layer includes: an aperture exposing a part of middle portions of the first anode electrode.

3. The light emitting display device according to claim 2, wherein the second anode electrode is disposed on an upper surface of the insulating layer.

4. The light emitting display device according to claim 2, wherein the insulating layer has an island shape on the first anode electrode, and
wherein the aperture has a polygonal slit shape disposed within the insulating layer.

5. The light emitting display device according to claim 4, wherein the aperture has the polygonal slit shape having at least one of a horizontally elongated rectangle and a vertically elongated rectangle.

6. The light emitting display device according to claim 4, wherein the aperture has the polygonal slit shape having at least one of a ‘+’ shape and a ‘X’ shape in a middle of the insulating layer.

7. The light emitting display device according to claim 4, wherein the aperture has a plurality of polygonal slit shapes arranging at a regular interval.

8. The light emitting display device according to claim 2, wherein an inclination angle of a sidewall of the insulating layer is in a range of 45 degree to 75 degree.

9. The light emitting display device according to claim 2, wherein an inclined angle of a sidewall of the aperture in the insulating layer is in a range of 45 degree to 75 degree.

10. The light emitting display device according to claim 8, wherein a portion of the emission layer is disposed along the sidewall of the insulating layer, and a portion of the cathode electrode is disposed on the portion of the emission layer along the sidewall of the insulating layer so as to form a concave mirror structure.

11. The light emitting display device according to claim 2, wherein:
the insulating layer includes apertures;
the apertures include the aperture; and
a distance between the apertures is equal to or less than 20 μm.

12. The light emitting display device according to claim 2, wherein the second anode electrode is not in contact with the first anode electrode at a position where the aperture is formed.

13. The light emitting display device according to claim 1, wherein the first anode electrode and the second anode electrode include a transparent conductive material,
wherein the insulating layer includes a transparent insulating material, and
wherein the cathode electrode includes a metal material.

14. The light emitting display device according to claim 13, wherein the transparent conductive material includes at least one of indium tin oxide (ITO), indium zinc oxide (IZO), and indium zinc tin oxide (IZTO),
wherein the transparent insulating material includes any one of silicon oxide and silicon nitride, and
wherein the metal material includes any one of aluminum (Al), magnesium (Mg), calcium (Ca), silver (Ag), and an alloy thereof.

15. The light emitting display device according to claim 1, further comprising:
a passivation layer covering the driving element on the substrate;
a color filter corresponding to the emission area on the passivation layer;
a planarization layer covering the passivation layer and the color filter; and
a pixel contact hole formed at the non-emission area, the pixel contact hole penetrating the planarization layer, the color filter and the passivation layer to expose a portion of the driving element,
wherein the first anode electrode contacts the portion of the driving element via the pixel contact hole.

16. The light emitting display device according to claim 15, wherein the insulating layer covers the pixel contact hole.

17. The light emitting display device according to claim 15, wherein the insulating layer covers the non-emission area.

18. The light emitting display device according to claim 1, wherein a portion of the second anode electrode is deposited along a sidewall of the insulating layer so as to directly contact the circumferential portion of the first anode electrode.

19. The light emitting display device according to claim 18, wherein the portion of the second anode electrode completely surrounds an upper surface and a sidewall of the circumferential portion of the first anode electrode.

20. A light emitting display device, comprising:
a substrate;
a pixel on the substrate, the pixel including an emission area and a non-emission area;
a driving element located at the non-emission area;
a planarization layer covering the driving element;
a first anode electrode disposed at the emission area and a portion of the non-emission area, the first anode electrode being disposed on the planarization layer;
an insulating layer exposing circumferential portions of the first anode electrode, and covering an upper surface of the first anode electrode at the emission area;
a second anode electrode extending to cover an upper surface and a sidewall of the insulating layer, to contact the exposed circumferential portions of the first anode electrode, and to contact an upper surface of the planarization layer;
an emission layer on the insulating layer, the first anode electrode and the second anode electrode; and
a cathode electrode on the emission layer,
wherein the cathode electrode extends along the upper surface and the sidewall of the insulating layer.
